(19) United States
(12) Patent Application Publication
(10) Pub. No.: US 2015/0363263 A1
(43) Pub. Date: Dec. 17, 2015

(54) ECC Encoder Using Partial-Parity Feedback

(71) Applicant: HGST Netherlands B.V., Amsterdam (NL)

(72) Inventors: Martin Aureliano Hassner, Mountain View, CA (US); Kirk Hwang, Palo Alto, CA (US)

(21) Appl. No.: 14/303,393

(22) Filed: Jun. 12, 2014

(51) Int. Cl. G06F 11/10; H03M 13/11

(52) U.S. Cl. CPC G06F 11/1068; H03M 13/1134

(57) ABSTRACT

ECC Encoders that process packets of p bits (with p>1) in a data block in parallel and generate a set of N parity/check bits that are stored along with the original data in the memory block. Encoders according to the invention can be used to create a nonvolatile NAND Flash memory write cache with BCH-ECC for use in a disk drive that can speed up the response time for some write operations. Encoder embodiments of the invention use Partial-Parity Feedback along with a XOR-Matrix Logic Module, which calculates N output bits from p input bits, and a Shift Register Module that accumulates N check bits. The XOR-Matrix Logic Module is designed using a precalculated Matrix of p×N bits, which is translated into VHDL design language to generate the hardware gates. High-Order p-bit Partial-Parity Feedback improves over LFSR designs and achieves Minimal Critical Path Length:=p.

### FIELD OF THE INVENTION

The invention relates to the field of error correction codes (ECC) and ECC encoders and more particularly to ECC encoders for use in NAND Flash Memory controllers in devices such as disk drives, solid-state drives (SSDs) and mobile communication systems.

### BACKGROUND

A Flash memory module 101 typically includes a controller 10 is typically used to provide the host interface on one side and to control and access to an array of NAND Flash memory devices 10F as shown in FIG. 1A. The term “host” is used generically to mean the upstream part of the system that sends and receives data to the Flash controller. NAND Flash memory has many applications including in solid-state drives (SSDs). One of use is in “hybrid drives” that combine NAND Flash memory with disk drive technology to benefit from the speed of Flash memory and the cost-effective storage capacity of disk drives which store information magnetically on rotating disks. A Flash memory module in a disk drive can also be used in various ways including as a write cache for data ultimately to be stored on the magnetic disks for improved performance.

FIG. 1B is a block diagram of prior art disk drive 99 that includes a Flash memory module 101 that can be used for various purposes including as a write cache. U.S. Pat. No. 7,411,757 to Chu, et al. (Aug. 12, 2008) describes a hybrid disk drive with nonvolatile Flash memory having multiple modes of operation. The nonvolatile memory can be used in “standby” mode where the disks are spun down and additionally in a “performance” mode, one or more blocks of write data are destaged from the disk drive's volatile write cache and written to the disk and simultaneously to the nonvolatile memory. In a second additional mode, called a “harsh-environment” mode, the disk drive includes one or more environmental sensors, such as temperature and humidity sensors, and the nonvolatile memory temporarily replaces the disks as the permanent storage media. In a third additional mode, called a “write-inhibit” mode, the disk drive includes one or more write-inhibit detectors, such as a shock sensor for detecting disturbances and vibrations to the disk drive. In write-inhibit mode, if the write-inhibit signal is on then the write data is written from the volatile memory to the nonvolatile memory instead of to the disks.

A NAND Flash memory array is grouped into blocks, e.g. “128 KB” block, which must be erased as a unit. Erasing a block sets all bits to 1. A programming operation, which typically can be performed on byte units, changes erased bits from 1 to 0. Each block is further organized into a set of fixed sized pages, for example with each page nominally having 512 bytes, 2 KB, 4 KB, or 8 KB according to the design. For example, a “128 KB” block might have 64 pages that each store 2048 (2K) bytes data. However, each page will typically include additional “spare” bytes beyond the nominal data byte value of otherwise identical memory cells that can be used for ECC or other system functions. If there are 64 bytes of additional “spare” memory cells, the “2048-byte” page actually includes a total of 2112 bytes of memory.

NAND Flash memory devices typically require associated error correction code (ECC) systems to provide data integrity given the frequency of bad blocks. Flash memory controllers typically include an error correction code (ECC) encoder 10E capability that can be enabled when required. With ECC enabled a programming operation includes the generation of a set of redundant parity or check bits that are calculated using the data bytes to be stored in the sector or block. The ECC bits are written to the memory along with the corresponding data. When the data is read back, the ECC bits are also read, and the ECC Decoder 10D system uses the ECC bits for error detection and correction within the system's limitations. The number of errors that can be corrected depends on the design. When writing data and ECC information to a page, the ECC information can be written as a contiguous set of bytes that is, in effect, appended to the data, it is also possible to interleave data and ECC information. The ECC check bits are calculated from a predetermined unit of data, which does not necessarily correspond to the page size. Thus the ECC unit is sometimes called a sector to distinguish it from a page.

ECC engines (encoders and decoders) can be embedded in the controller chip hardware or ECC can be provided externally by hardware or software. A NAND Flash controller can implement on-the-fly correction by using a buffer to store data while the ECC decoder performs the computations needed for the correction. The ECC algorithms that are often mentioned for use with Flash memory are Hamming codes, Reed-Solomon codes and BCH codes. Bose-Chaudhuri-Hocquenghem (BCH) codes, which are a type of cyclic error-correcting codes that use finite fields, are the subject of the present application. BCH codes are advantageous in that they allow an arbitrary level of error correction and are relatively efficient in the number of gates required in a hardware implementation.

A multi-bit error correction based on a BCH code for a memory is described in US patent application 20120311399 by Yufei Li, et al., published Jun. 12, 2012. The error correction process includes repeatedly shifting the BCH code and, at the same time, determining whether the number of errors decreases.

In US patent application 2011/0185265 by Cherukari, published Jul. 28, 2011, agile encoder for encoding a linear cyclic code such as a BCH code. The generator polynomial for the BCH code is provided in the factored form. The number of factored polynomials (minimal polynomials) chosen by the system determines the strength of the BCH code. The strength can vary from a weak code to a strong code in unit increments without a penalty on storage requirements for storing the factored polynomials.

U.S. Pat. No. 6,519,738 to J. Derby (Feb. 11, 2003) describes a cyclic redundancy code (CRC) computation based on state-variable transformation. The method computes a CRC of a communication data stream taking a number of bits M at a time to achieve a throughput equaling M times that of a bit-at-a-time CRC computation operating at a same circuit clock speed. The method includes (i) representing a frame of the data stream to be protected as a polynomial input sequence; (ii) determining one or more matrices and vectors relating the polynomial input sequence to a state vector; and (iii) applying a linear transform matrix for the polynomial input sequence to obtain a transformed version of the state vector.

U.S. Pat. No. 7,539,918 to Keshab Parhi (May 26, 2009) also describes a method for generating cyclic codes for error control in digital communications.

U.S. Pat. No. 8,286,059 to C. Huang, Oct. 9, 2012, describes a word-serial cyclic code encoder. The cyclic code encoder adds input words to output register words, generating a feedback word, which can be supplied through a feedback loop that selectively transmits feedback words through weight arrays and intra-register adders, to the input of word registers. A controller can operate the cyclic code encoder in either an input mode or an output mode during which feedback words can be sequentially transmitted on the feedback loop and the states of the word registers can be updated and the final states of the word registers can be sequentially shifted out of the output word register as parity words, respectively.

Linear feedback shift registers (LFSR) are used in the cyclic redundancy check (CRC) operations and BCH encoders. Manohar Ayinala, et al. have discussed unfolding techniques for implementing parallel linear feedback shift register (LFSR) architectures. (Manohar Ayinala, et al., High-Speed Parallel Architectures for Linear Feedback Shift Registers; IEEE TRANSACTIONS ON SIGNAL PROCESSING, VOL. 59, NO. 9, SEPTEMBER 2011, pp. 4459-4469.) FIGS. 1C-1D illustrate LFSR-Unfolding according to the prior art. The article presents a mathematical proof of existence of a linear transformation to transform LFSR circuits into equivalent state space formulations. The method applies to all generator polynomials used in CRC operations and BCH encoders. A method is proposed to modify the LFSR into the form of an infinite impulse response (IIR) filter. The proposed high speed parallel LFSR architecture is based on parallel IIR filter design, pipelining and retiming algorithms. The approach has both feedforward and feedback paths. Combined parallel and pipelining techniques are said to eliminate the fan-out effect in long generator polynomials.

Recent FLASH memory applications require an ECC encoder that cannot be implemented by a standard bit-serial Linear Feedback Shift Register (LFSR). The prior art attempts to solve these two problems by ‘LFSR-Unfolding’ and Chinese-Remainder-Theorem (CRT), where LFSR-unfolding solves the multiple bit throughput problem and CRT addresses the long ‘fan-out’ problem that limits the frequency at which the encoder can be used. There is a need to provide one solution that solves both problems.

### SUMMARY OF THE INVENTION

Embodiments of the invention are methods of encoding and ECC Encoders that process packets of p bits (with p>1) in a data block in parallel and generate a set of parity/check bits that are stored along with the original data in the memory block and allow correction of errors when the block is read back. Encoders according to the invention can be used to create a nonvolatile NAND Flash memory write cache with BCH-ECC for use in a disk drive that can speed up the response time for some write operations. The terms “parity bits” and “check bits” are used interchangeably herein. Embodiments can be designed to efficiently provide correction of a very large number (t) of bit errors in a data block during read back. Encoder embodiments of the invention use Partial-Parity Feedback along with a XOR-Matrix Logic Module, which calculates N output bits from p input bits, and a Shift Register Module that accumulates N check bits, where N is the number of parity/check bits for the data block and N is greater than p. The XOR-Matrix Logic Module is designed using precalculated Matrix of p×N bits, which is translated into VHDL design language to generate the hardware gates. High-Order p-bit Partial-Parity Feedback improves over LFSR designs and achieves Minimal Critical Path Length:=p.

Embodiments of the present invention precalculate the entries for the Matrix by finding the remainder polynomials of all the single-bit inputs, within a p-bit window-input, and constructing a p×N basis matrix that can be directly converted to VHDL-XOR-logic. The p-bit Partial-Parity Feedback used, which is the length of the critical path, is much smaller than the LFSR-feedback, and is optimal, as it is equal to the ‘bus width’. The selected value for p is predetermined by the design. An exemplary embodiment uses p=16, but higher or lower values can be selected according to the principles of the invention. Higher values for p imply wider bus widths and increased speed at the expense of more circuitry.

As the packets of p bits are iteratively processed, the highest p bits in the Shift Register from the previous cycle are shifted out and fed back as the Partial Parity Feedback to be XOR'ed with the next p-bit input packet. The lowest p bits in the Shift Register are loaded with zeroes on each cycle. The XOR Array Multiplier iteratively accepts packets of p bits as input and generates parallel output of N bits that are fed to the Shift Register Module which XOR's the shifted contents of the Shift Register to generate the new Shift Register content. The contents of the Shift Register, at the end of iteratively processing the set of packets for the input data unit, are the N check bits corresponding to the data block.

An exemplary embodiment for an ECC block with 1088 data bytes (2-pages of 544 bytes each) uses p=16, t=42 bit-correction capability with a Galois-Field (GF(2̂14)) for N=588 bits required parity bits and a 588-bit Shift Register. The XOR-Matrix Logic Module accordingly has 16-bit wide data input, and 588-bit parity output to the 588-bit Shift Register Module. The output parity bits are in low-to-high order and the 16-bit data input is in high-to-low order. The final set of parity values, accumulated in 588-bit Shift Register are read out in high-to-low order, i.e. in the reverse order.

In the exemplary embodiment the input data is processed in 16-bit packets. The 588-bit Shift Register is initialized with zeroes. At the start of each cycle the contents the 588-bit Shift Register are shifted up 16 bits and the most significant 16 bits, which are shifted out, are latched for use as the Partial-Parity Feedback into the first processing stage. As 16 bits are shifted out at the top, 16 bits of zeroes are shifted in at the bottom of the Shift Register. Each 16-bit packet is XOR'ed with the latched 16 bits that were shifted out from the 588-bit Shift Register. The result of the first stage is then multiplied by the 16-by-588 Matrix to produce a new 588-bit second stage output that is XOR-ed with the shifted 588-bit Register content to form the new Shift Register content. This cycle is repeated until the last 16-bit packet has been processed. The final 588 bits in the Register are clocked out and stored with of the data block. The design and operation of the Decoder follows from the specification of the Encoder as described herein and can be otherwise implemented using prior art principles.

### BRIEF DESCRIPTION OF THE FIGURES

FIG. 1A is a block diagram illustration of NAND Flash Module arrangement according to the prior art.

FIG. 1B is a block diagram illustration of a disk drive with a NAND Flash Module according to the prior art.

FIGS. 1C and 1D illustrate LFSR-Unfolding described in the prior art. In FIG. 1B LFSR is used to process the message as a serial input. LFSR-Unfolding creates a p-parallel LFSR, as illustrated in FIG. 1C, that can process p-bit “packets”.

FIG. 2 is block diagram illustration of an Encoder according to an embodiment of the invention.

FIG. 3 is block diagram illustration of a Register Module for use in an encoder according to an embodiment of the invention.

FIG. 4 is flowchart diagram illustration an encoding method according to an embodiment of the invention.

FIG. 5 is an example of 42 binary polynomials of degree 14 each that are used to calculate an encoder polynomial used in an embodiment of the invention.

FIG. 6 is an encoder polynomial “g_{—}{588}(y)”, which is shown as a list of coefficients in increasing “power order”, 1+ŷ4+ŷ5+ŷ6+ . . . that is used in an embodiment of the invention.

### DETAILED DESCRIPTION OF THE INVENTION

An ECC encoder embodiment of the invention can be used in various applications, but in particular a Flash memory controller with an ECC encoder embodiment of the invention can be included in a disk drive for use, for example, as a write cache, to create a nonvolatile memory (NVM) with BCH-ECC that will speed up the response time for certain commands while ensuring high data reliability.

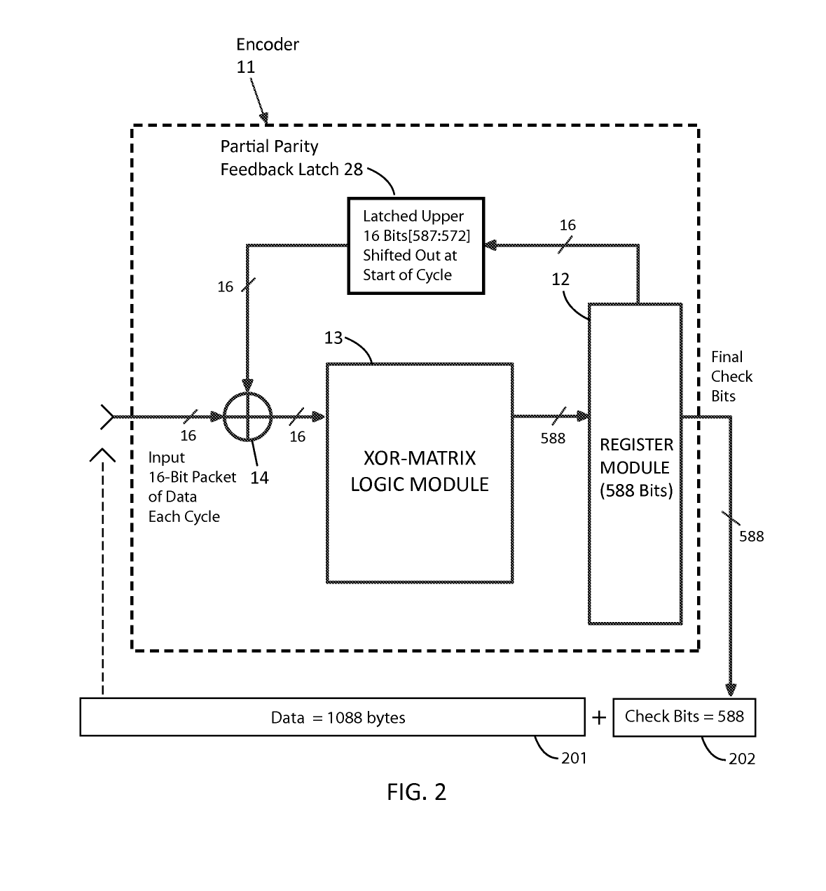

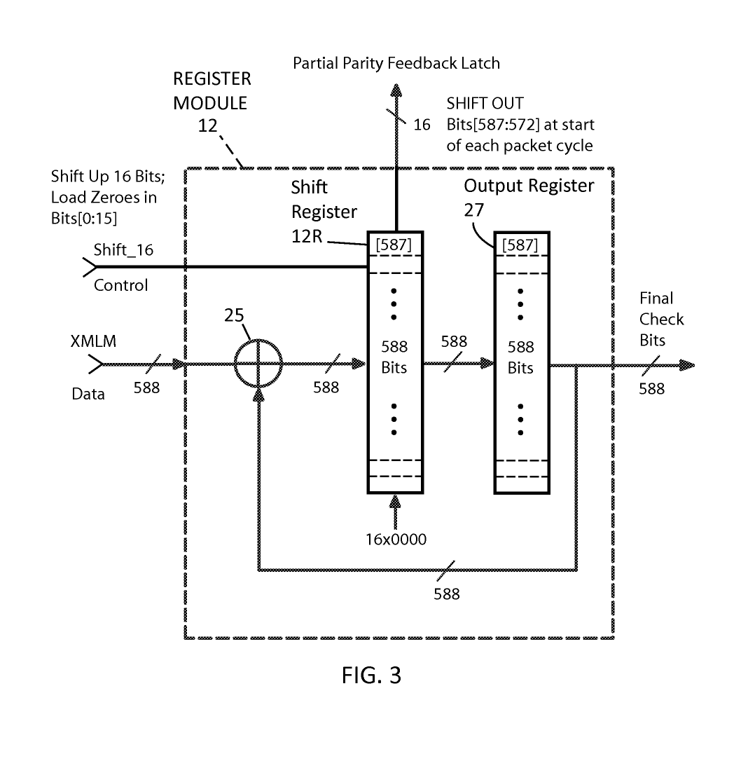

An ECC Encoder 11 embodiment of the invention including XOR Matrix Logic Module 13, Register Module 12, Partial-Parity Feedback Latch 28 and XOR input module 14 is illustrated in FIG. 2. FIG. 3 is a block diagram illustration of the selected components in a Register Module 12 according to an embodiment the invention. The input data stream is processed packets of p=16 bits and Partial-Parity Feedback is the 16 high-order bits of the Shift Register 12R. This exemplary embodiment is for a 1088 bytes data block 201, e.g. 2-page (544 data bytes each page) ECC block. The correction capability is t=42 bit-correction. The underlying Galois-Field used in the design is GF(2̂14) for N=588 bits required parity bits. The XOR Matrix Logic Module (XMLM) 13 accordingly has 16-bit wide data input and 588-bit output to the Register Module 12. XOR Matrix Logic Module 13 includes circuitry that translates or maps 16-bit input into 588-bit output (p×N bits). The Register Module 12 manages the content of a 588-bit memory Shift Register 12R and a 588-bit Output Register 27 shown in FIG. 3 and supplies Partial-Parity Feedback to the initial XOR input stage 14 through Partial-Parity Feedback Latch 28.

The Encoder 11 processes packets of 16 bits at a time; therefore, 544 iterations/cycles are needed to process the 1088 byte data block 201 and generate the 588 check bits 202 that will be stored along with the original data in the Flash memory. The Shift Register 12R and Output Register 27 are initialized to all zeroes at the start of each data block. In each 16-bit cycle iteration the contents of the Shift Register are shifted up 16 bits in response to the Shift_16 Control line and the lowest 16 bits in the Shift Register are loaded with zeroes. Thus, as 16 bits are shifted out at the top, 16 bits of zeroes are shifted into the bottom of the Shift Register. The highest 16 bits in the Shift Register (which are from the previous cycle except for the first iteration) are shifted out and stored in Partial-Parity Feedback Latch 28 which feeds the bits back to be XOR'ed with the 16-bit input packet by XOR Module 14. The contents of the Shift Register after the shift operation are loaded into Output Register 27 as part of each iteration. In the last iteration, the final contents of the Shift Register are loaded into Output Register 27 without shifting to supply the final check bits at the end of the process. Output Register 27 also the supplies input back to XOR module 25, which also has input from the XOR Matrix Logic Module (XMLM) 13.

The XOR Matrix Logic Module 13 iteratively accepts packets of p bits (with p=16) as input and generates parallel output of N bits (with N=588) that are fed to the Register Module 12. Register Module 12 XOR's the new input with the current contents of the Output Register 27 to generate the new Shift Register content. The contents of the Output Register, at the end of iteratively processing the set of packets for the input data block, are the N check bits corresponding to the data block. In this embodiment the output check/parity bits are in low-to-high order and the 16-bit data input is in high-to-low order. The final set of parity/check values, accumulated in 588-bit Output Register are read out in high-to-low order, i.e. in the reverse order.

Each 16-bit input packet is XOR'ed with the Partial-Parity Feedback Latch's 16-bits by the XOR logic module 14 which generates a 16-bit result that is input into the XOR Matrix Logic Module (XMLM) 13. The XMLM takes the output of XOR logic module 14 and produces a 588-bit second stage output that is sent to Register Module 12. Register Module 12 XOR's the new input with the current/old 588-bit Register content to form the new Shift Register content. This cycle is repeated until the last 16-bit packet has been processed. The final 588-bits in the Output Register are clocked out and stored with of the data block.

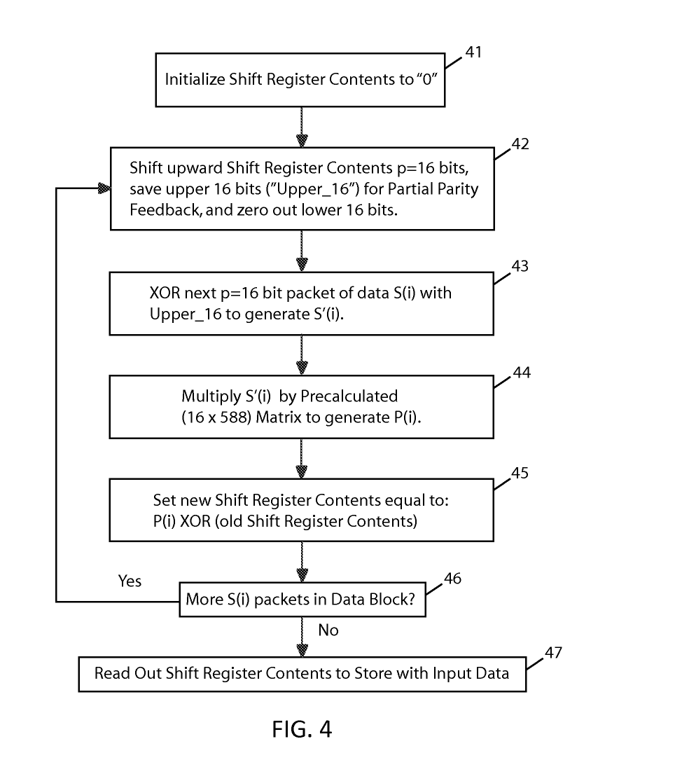

FIG. 4 is flowchart diagram illustration an encoding method according to an embodiment of the invention, which uses Partial-Parity Feedback and XOR Matrix Logic Module 13 as illustrated in FIG. 2. At the start of processing for each data block (e.g. 1088 bytes), the Shift Register is initialized as all zeroes 41. The iterated processing loop begins by shifting the contents of the Shift Register upward by p bits, which is 16 bits in this embodiment 42. The lowest 16 bits become “0”. The highest 16 bits (e.g. [587:572]; which will be called “Upper_16”) are shifted out of the register but are saved (latched) for use as the Partial-Parity Feedback in the next step. The loop processes the next 16-bit packet “S(i)” of the input data block by XOR'ing S(i) with the Upper_16 bits to generate the result S′(i) which is also 16 bits 43. The S′(i) is then translated 44 into P(i), which is 588 bits. Each of the 588 bits in P(i) is a predetermined function of selected bits in the S′(i), which is further described below.

The P(i) result is then XOR'ed with the (old) content of the Shift Register to derive the new content of the Shift Register 45. Note that in the hardware diagram in FIG. 3, the separate Output Register is used to facilitate this operation by allowing the old content of the Shift Register to be fed back to XOR logic while the new content is being created. The encoding cycle iterates until the last package of bits in the block has been processed 46. The 588-bit content of the Shift Register is then read out as the set of check bits to be stored with the data block 47. The separate Output Register can be used to facilitate the read out operation.

The predetermined functions that map the p bits in S′(i) to N bits in P(i) are determined by generating a p×N Matrix. Embodiments of the present invention precalculate the entries for the Matrix by finding the remainder polynomials of all the single-bit inputs, within a p-bit window-input, and constructing a p×N basis matrix that can be directly converted to VHDL-XOR-logic. The p-bit feedback used, which is the length of the critical path, is much smaller than the LFSR-feedback, and is optimal, as it is equal to the ‘bus width’.

The assumed design parameters require a high bit-correction “t=42” capability for a 2-page (544 byte each) total block of 8*2*544=8,704-bit. This number is bigger than 2̂13, but smaller than 2̂14, thus the Galois-Field (GF) required to locate bit-errors within the 8,704 data-block is GF(2̂14), thus the number of required parity bits, to correct 42 bit-errors, is 42*14=588 bits. The coded data block thus consists of 8,704 data-bits+588 parity bits=9,292, however, this number is not divisible by 14, to make it divisible by 14 requires a “pad” of 4 bits, thus making the coded block-size=9,296, hence the BCH-Code is [k=8,704, n=9,296, t=42], where “k” is the number of uncoded data bits, “n” is the number of coded block bits and “f” is the bit-correction capability.

An additional assumed requirement of the design is that data is processed at a rate of “p=16”/system clock, i.e. the encoder/decoder hardware has to process the data in 16-bit “packets”. A system with an 16-bit wide/588-bit Binary Encoder Encoder according to an embodiment of the invention should also include corresponding Decoder that will include Functional Units of:
16-bit wide/1176-bit Binary Syndrome Generator
Key-Equation-Solver [GF(2̂14)]
Chien Search [GF(2̂14)]
   The design and operation of the Decoder follows from the specification of the Encoder as described herein and can be otherwise implemented using prior art principles.

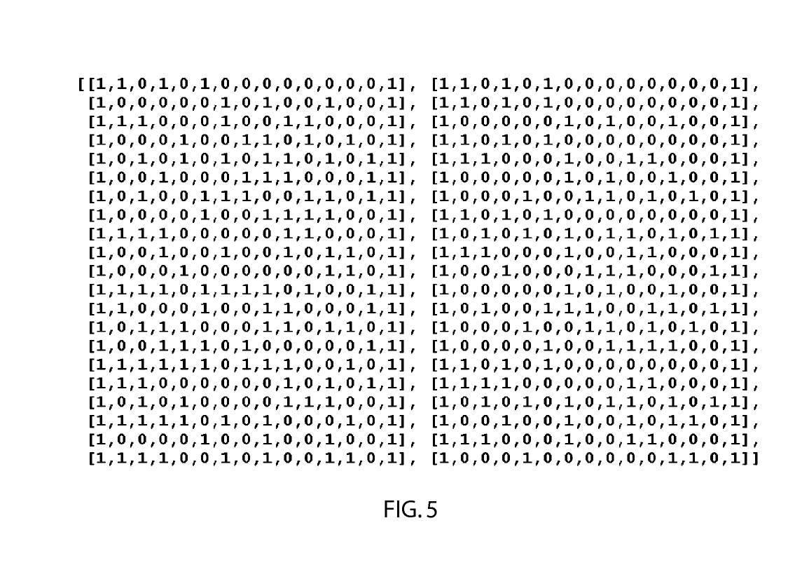

FIG. 5 is an example of 42 binary polynomials of degree 14 each arranged in two columns and delineated by brackets. This set of polynomials are used to calculate an encoder polynomial used in an embodiment of the invention. The algebraic calculation of the Encoder Polynomial uses 42 binary polynomials of degree 14 each, each associated with one of its 42 primitive roots, using Mathlab syntax is as follows:

minpolk(k:kNNI):POLY PF 2 == |
resultant(resultant(y−(u*v+1)\hat{ }k,u\hat{ }7+u+1,u),v\hat{ }2+v+1,v)
minpols:=[minpolk((2*k−1) for k in 1..42];
fminpols:=[factor(minpols.k) for k in 1..#minpols];
chkMinPols:=[fminpols.k+minpols.k for k in 1..42]
g42:=lcm(minpols);

The generator polynomial “g(y)” of a t-bit error correcting BCH-Code, of block size “2̂(m−1)<N<2̂(m)”, is the least-common-multiple (LCM) of the minimum polynomials of its roots “g(âi)=0”, i=1, . . . , 2t”, where “a” is the primitive element of the Galois Field “GF(2̂m)”. The block N requires “m=14”, where the Galois Field GF(2̂14) is generated by a quadratic extension of GF(2̂7). Since the application requires “t=42”, calculation of 42 minimal polynomials is required, each of degree “m=14” and, since they have no common factors, their “LCM” equals to their product, a binary polynomial “g(y)” of degree 14*42=588.

The calculation of these 42 minimal polynomials is effectively done by resultants, using standard mathematics. The resultant of two polynomials can be computed using standard computer algebra systems. The resultant of two polynomials is a polynomial expression of their coefficients. There are two nested resultant calculations “resultant {resultant [y−(u*v+1)̂k,û7+u+1, u],v̂2+v+1,v}, for k=1, . . . , 42”. The first resultant calculation uses “û7+u+1” [which generates GF(2̂7)], and the second uses “v̂2+v+1”, which is the quadratic extension of GF(2̂7) to GF(2̂14). The output of this calculation is a list of 42 polynomials in the variable “y”, of degree 14 each, that have no common factor. Their product is the degree-588 generator polynomial “g(y)”.

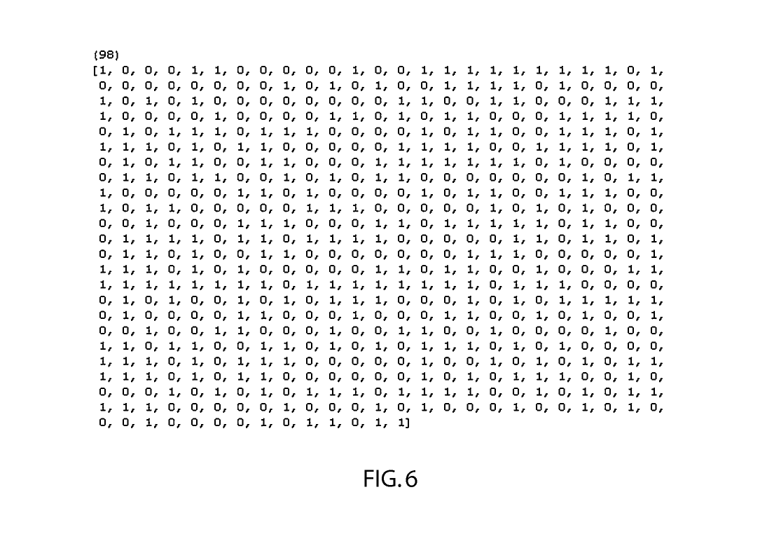

These 42 polynomials have no common factors; thus their product, a polynomial of degree 42*14=588, is the encoder polynomial “g_{—}{588}(y)”, shown in FIG. 6, which is a list of 589 coefficients in increasing “power order”, 1+ŷ4+ŷ5+ŷ6+ . . . .

A textbook Linear-Feedback-Shift-Register (LFSR), which is the standard circuit for implementing a BCH-Encoder, is a shift register that is hardwired by the binary coefficients of the encoder polynomial. For the application described herein this register would be 588-units long, and its critical path feedback would be too long for a 270-MHz clock implementation. Furthermore it is a single-bit bus encoder.

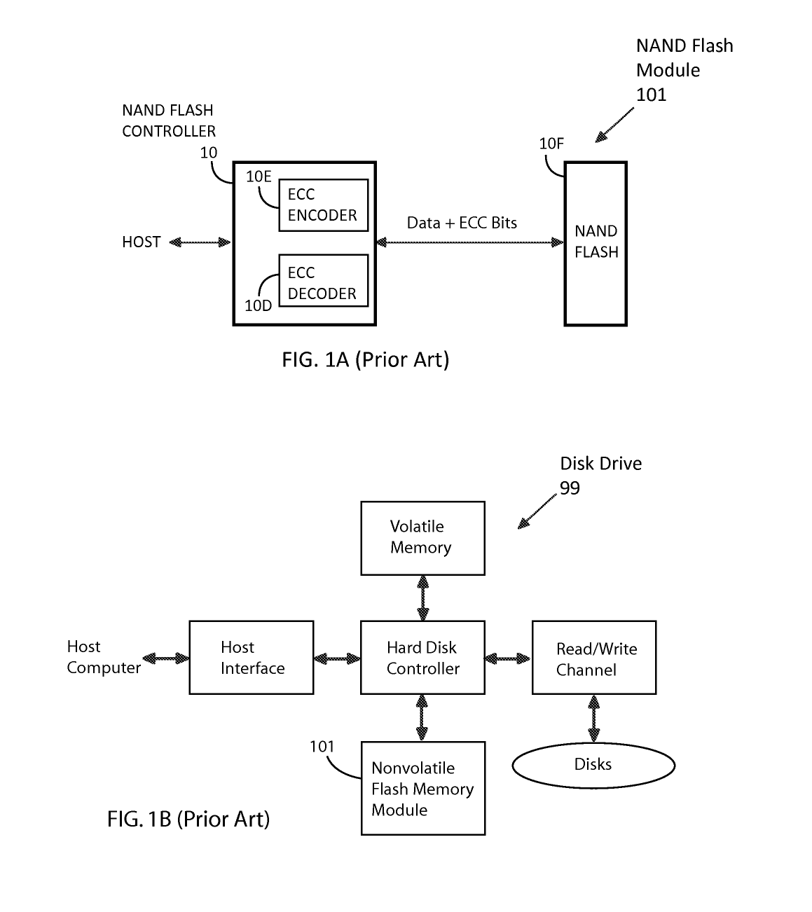

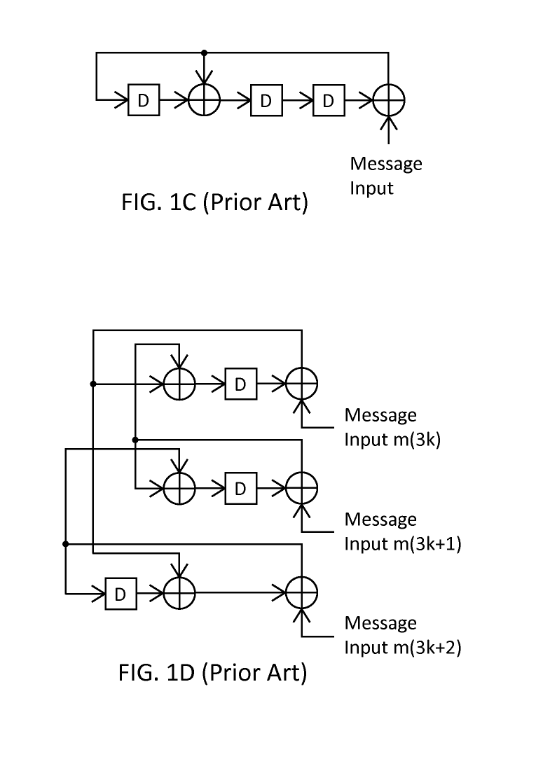

The solution of these two problems in embodiments of the invention results in the implementation of a minimal critical path, high-speed parallel BCH ECC encoder. The Ayinala 2011 article cited above provides background on LFSR-Unfolding concepts. FIGS. 1C-1D illustrate LFSR-Unfolding according to the prior art. In FIG. 1C LFSR is used to process the message as a serial input. LFSR-Unfolding creates a p-parallel LFSR, as illustrated in FIG. 1D, that can process p-bit “packets”, but does not satisfactorily solve the minimal critical path problem.

CRT reduces the critical path feedback by parallel division of the data input, by the individual 42 polynomials of degree 14 each, but it is still a single bit input processor. Thus prior art LFSR unfolding solves LFSR “p-Parallel Bit” Encoding and Chinese-Remainder-Theorem (CRT) can be used to reduce LFSR “t*m” Critical Path Length [where “m”:=Error Locator GF Size].

The disclosed solution in embodiments of the present invention results in “p-by-rm” XOR-VHDL Matrix-Encoder with High-Order “p”-bit Partial-Parity Feedback which eliminates LFSR while solving both stated problems and achieving Minimal Critical Path Length:=“p”.

The calculation of the minimal critical path feedback/programmable parallel-p-packet BCH encoder 11 solution, as shown in FIG. 2 is as follows for a 16×588 XOR VHDL-Matrix. By Computer Algebra Calculation, the response of a 588-long LFSR to single bits within a 16-bit window input is precalculated. For each single bit position, within a 16-bit input pattern, we calculate the remainder polynomial that is the result of dividing the input polynomial by the LFSR-polynomial, resulting in 16 remainder polynomials {rₖ(y)}, k=0, . . . , 15 as shown in equ-1:

$${r}_{k} ( y ) = rem ( \frac{{y}^{587 + k + 1}}{{g}_{42} ( y )} ) , \\ k = 0 , 1 , … , 15 \qquad ( equ \text{-} 1 )$$

The coefficients of these polynomials form a Boolean matrix (e.g. “tmatarray”), of 16-by-588:

tmatarray=transpose(matrix[coefficients(rₖ(y)]) (equ-2)

This Matrix is directly translated into standard hardware description language VHDL (VHSIC Hardware Description Language) Logic, as illustrated below. There are 16 input bits (i:in bit_vector(0 to 15)) and 588 output bits (o:out bit_vector(0 to 587)). Each of the output bits is a predetermined function of selected input bits. For example, the first output bit defined below “o(0)” is the XOR of input bits 0, 4, 5, 7, 9, 10, 11, 12, and 14. Output bits o(6) through o(584) are omitted for brevity. The omitted entries are determined as described above.

```
entity tmatarray is port(
  i : in bit_vector(0 to 15);
  o : out bit_vector(0 to 587) );
end tmatarray;
architecture tmatarray_arch of tmatarray is
  begin
```

```
o(0) <= i(0) xor i(4) xor i(5) xor i(7) xor i(9) xor i(10) xor i(11) xor
  i(12) xor i(14);
o(1) <= i(1) xor i(5) xor i(6) xor i(8) xor i(10) xor i(11) xor i(12) xor
  i(13) xor i(15);
o(2) <= i(0) xor i(2) xor i(4) xor i(5) xor i(6) xor i(10) xor i(13);
o(3) <= i(0) xor i(1) xor i(3) xor i(4) xor i(6) xor i(9) xor i(10) xor
i(12);
o(4) <= i(0) xor i(1) xor i(2) xor i(9) xor i(12) xor i(13) xor i(14);
o(5) <= i(0) xor i(1) xor i(2) xor i(3) xor i(4) xor i(5) xor i(7) xor i(9)
xor i(11) xor i(12) xor i(13) xor i(15);
  ...
o(585) <= i(1) xor i(2) xor i(4) xor i(6) xor i(7) xor i(8) xor i(9) xor
i(11) xor i(13) xor i(15);
o(586) <= i(2) xor i(3) xor i(5) xor i(7) xor i(8) xor i(9) xor i(10) xor
i(12) xor i(14);
o(587) <= i(3) xor i(4) xor i(6) xor i(8) xor i(9) xor i(10) xor i(11)
  xor i(13) xor i(15);
```

```
  -- max row xor count = 12
  -- max latency is 4 xors
  -- total xor count = 4204
  end tmatarray arch;
```

The resulting circuit architecture embodiment of the invention shown in FIG. 2, achieves a minimal critical path feedback, the bus-width “p=16”, and is defined by a logic gate-array of “p-by-rm”, where “p:=16, t:=42, m:=14”, are the design parameters. This design is flexible, if “p:=32” bus-width is required we can reprogram this gate-array, by redoing the calculations using a “p:=32” window and calculating 32-remainder polynomials instead of 16. Therefore, embodiments of the invention can be scaled up to wider bus widths for increased speed if required.

1. An error correction code encoder that generates a set of check bits for an input data block for a device by iteratively processing p-bit packages of data in the data block comprising:
a shift register module that includes a shift register including N bits of memory that are initialized to zeroes for each data block, where p is greater than one, and N is greater than p, input to the shift register module being N bits of data that are XOR'ed with current content shift register to generate a new content of the shift register, and shift register module shift operation shifting bits in the shift register upward by p bits and loading zeroes into lower order p bits in the shift register;
a partial parity feedback latch that stores high order p bits shifted out of the shift register;
an XOR logic module with a first input path supplying a p-bit package of the input data and a second input path connected to the partial parity feedback latch, and an output of a first set of p-bits; and
an XOR matrix logic module that translates the first set of p-bits into an output of N bits using a predetermined mapping and feds the output of N bits to the input of the shift register module;
wherein the error correction code encoder generates the set of N check bits for an input data block in the shift register by iteratively processing successive p-bit packages of data in the data block.

2. The error correction code encoder of claim 1, wherein the set of N check bits form a type of Bose-Chaudhuri-Hocquenghem (BCH) code.

3. The error correction code encoder of claim 1, wherein the p-bit data input is in high-to-low order and the set of N check bits in the shift register are in low-to-high order.

4. The error correction code encoder of claim 1 wherein p is 16 and N is 588.

5. The error correction code encoder of claim 4 wherein up to 42 bit errors can be corrected in the data block using the set of 588 check bits.

6. The error correction code encoder of claim 5 wherein XOR matrix logic module is designed using a Galois Field GF(2̂14).

7. The error correction code encoder of claim 1 wherein the device is a NAND Flash memory controller.

8. The error correction code encoder of claim 2 wherein the NAND Flash memory controller is a component of a disk drive.

9. A method of generating error correction code check bits for an input data block in a device, the method comprising:
initializing a shift register containing including N bits of memory to zeroes;
iteratively process each packet of p bits in the input data block, where p is greater than one and N is greater than p, by:
generating a first set of N bits by shifting bits in the shift register upward by p bits and zeroing p lowest order bits in the shift register, and storing p highest order bits that are shifted out of the shift register as Partial-Parity Feedback;
XOR'ing a next packet of p bits in the input data block with the Partial-Parity Feedback to generate a first output of p bits;
using the first output of p bits to generate a second set of N bits where each bit is a predetermined of selected bits in first output of p bits; and
XOR'ing the first set of N bits with the second set of N bits to generate a third set of N bits and storing the third set of N bits in the shift register; and
after all packets of p bits in the input data block have been processed, storing the set of N bits in the shift register as the error correction code check bits for the input data block in the device.

10. The method of claim 9 wherein the error correction code check bits form a type of Bose-Chaudhuri-Hocquenghem (BCH) code.

11. The method of claim 10 wherein the Bose-Chaudhuri-Hocquenghem (BCH) code uses a Galois Field of GF(2̂14).

12. The method of claim 9 wherein p is 16 and N is 588.

13. The method of claim 12 wherein up to 42 bit errors can be corrected in the data block using the set of 588 check bits.

14. The method of claim 9 wherein the device is a NAND Flash memory controller.

15. The method of claim 14 wherein the NAND Flash memory controller is a component of a disk drive.
